(19) United States
(12) Patent Application Publication
(10) Pub. No.: US 2026/0266547 A1
(43) Pub. Date: Sep. 10, 2026

(54) FURNACE TUBE AND CONTROL METHOD THEREFOR

(71) Applicant: Changzhou S.C. Exact Equipment Co., Ltd., Changzhou City (CN)

(72) Inventors: Wei YI, Changzhou City (CN); Jinsheng Deng, Changzhou City (CN); Caozheng Li, Changzhou City (CN); Meishi Li, Changzhou City (CN); Jingdian Tan, Changzhou City (CN)

(21) Appl. No.: 19/663,428

(22) Filed: Apr. 30, 2026

Related U.S. Application Data
(63) Continuation of application No. PCT/CN2025/083792, filed on Mar. 20, 2025.

(30) Foreign Application Priority Data
Apr. 15, 2024 (CN) 202410450746.6

(51) Int. Cl. F27D 1/18; F27D 3/12; F27D 9/00; F27D 99/00

(52) U.S. Cl. CPC F27D 1/1858; F27D 1/1808; F27D 3/12; F27D 9/00; F27D 99/007

(57) ABSTRACT

Provided are a furnace tube and a control method therefor in the solar photovoltaic industry. The furnace tube includes an outer furnace tube, an inner furnace tube, an upper furnace cover, a lower furnace door, and a rotating device. An upper end and a lower end of an accommodating space between the inner furnace tube and the outer furnace tube are sealed to form a sealed chamber. A plurality of carrier placement positions correspondingly arranged in the sealed chamber by the rotating device can be used for enabling carriers to adjust positions and angles within the sealed chamber.

### CROSS-REFERENCE TO RELATED PATENT APPLICATION

This application is a continuation application of International Patent Application No. PCT/CN 2025/083792, filed on Mar. 20, 2025, which itself claims priority to Chinese Patent Application No. CN 202410450746.6 filed in China on Apr. 15, 2024. The disclosures of the above applications are incorporated herein in their entireties by reference.

### TECHNICAL FIELD

The present invention relates to the technical field of solar energy, and particularly relates to a furnace tube and a control method therefor.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In current photovoltaic industry, processes such as diffusion, oxidation, annealing, doping, PECVD, and LPCVD are carried out using a vertical furnace and a horizontal furnace. For the structures of these two types of furnaces, it is needed to place silicon wafers in specific carriers and transfer into a reaction chamber for processing. By introducing specific reaction gases, processes such as coating, diffusion, oxidation, and thin-film deposition on the silicon wafers can be carried out. In existing two-layer furnace tube design, both ends of the double-layer furnace tube are sealed using a base and a top wall to form a through-type cavity, the wafers to be processed are placed inside the through-through cavity, and heating layers on the double-layer furnace tube are used for heating the through-through cavity.

In the existing technology, a support structure for the carrier inside the furnace tube is fixed and cannot be adjusted by position or angle. This fixed placement of the carrier will cause local non-uniformity in a gas field and a thermal field when the reaction gases are introduced or there are temperature differences during heating, resulting in poor uniformity and significant differences in process uniformity at the ends and tails of the carrier during decomposition and reaction with the silicon wafer at high temperatures. This affects the overall process yield and causes inconsistency in the quality of cells produced in the same batch.

### SUMMARY

The present invention provides a furnace tube and a control method therefor, aiming to solve the technical problem that the position of a carrier in an inner furnace tube is fixed and the uniformity is poor in existing technology.

The technical solution adopted in the present invention is as follows:

The furnace tube provided by the present invention includes an outer furnace tube, an inner furnace tube, a lower furnace door, heating sources, and a rotating device; the inner furnace tube is mounted in the outer furnace tube; the lower furnace door is mounted at lower ends of the outer furnace tube and the inner furnace tube; an upper end and a lower end of an accommodating space between the inner furnace tube and the outer furnace tube are sealed to form a sealed chamber; the heating sources used for heating the sealed chamber are arranged on the inner furnace tube and the outer furnace tube; the rotating device is provided with a plurality of carrier placement positions corresponding to the sealed chamber; and the rotating device in rotating is capable of driving carriers on the carrier placement positions to adjust positions and angles within the sealed chamber.

Further, the upper end and the lower end of the inner furnace tube are opened, a connecting member used for hoisting connection is arranged at the opening in the upper end, while a support platform is arranged at the opening in the lower end.

Further, a central hole is formed in the middle of the lower furnace door, and a magnetic fluid assembly located at the central hole is further arranged outside the lower furnace door; the magnetic fluid assembly is in sealed connection with an inner edge of the lower furnace door and a support base at the bottom of the inner furnace tube; and a transmission shaft connected to the rotating device is arranged at a position, in sealed connection with the lower furnace door and the support base at the bottom of the inner furnace tube, of the magnetic fluid assembly.

Further, the rotating device includes: a boat holder base which is arranged in the sealed chamber of the furnace tube and provided with a plurality of carrier placement positions, the boat holder base being connected to the transmission shaft of the magnetic fluid assembly; and a rotating power source which is located outside the sealed chamber and connected to the transmission shaft to drive the boat holder base to rotate.

Further, the plurality of carrier placement positions on the rotating device are distributed around the inner furnace tube and are distributed into a plurality of layers in a height direction.

In an Embodiment 1, the boat holder base includes:
a rotating base which is located at the bottom of the sealed chamber; and
a hanging plate which is arranged on the rotating base and is provided with the plurality of carrier placement positions for hanging the carriers.

Further, a heat shield is arranged on the rotating base; the bottom of the hanging plate passes through the heat shield and vertically extends upwards; and a water cooling assembly is mounted in the heat shield.

In an Embodiment 2, the boat holder base includes:
the rotating base which is provided with the plurality of carrier placement positions for allowing carrier boats to pass through or be placed; and
a plurality of pairs of bearing members, each pair of bearing member being located on edges of both sides of one carrier placement position and being arranged on the rotating base in a foldable manner;
after switching the bearing members into a folded state, the carriers are capable of upwards passing through the carrier placement positions corresponding to the bearing members from the bottom; and after switching the bearing members into an unfolded state, the carriers are placed on the bearing members.

Further, an upper furnace cover is mounted at an upper end of the furnace tube; the central hole is formed in the middle of the upper furnace cover; and the central hole in the upper furnace cover is capable of penetrating the upper end of the inner furnace tube or penetrating a hoisting member that is connected to the upper end of the inner furnace tube.

Further, an outer end surface of the upper furnace cover away from the accommodating space protrudes outwards to form a spherical protrusion; a cavity is formed in the upper furnace cover around the periphery of the central hole; and a plurality of reinforcing ribs connected between an upper inner wall and a lower inner wall of the cavity are arranged in the cavity.

Further, a plurality of furnace ports penetrating the lower furnace door are formed in the lower furnace door, and the furnace ports are matched with side surfaces of the carriers in size and shape; each furnace port is correspondingly provided with a furnace cover, and the furnace cover is connected to a driving structure that is used for driving the furnace cover to be opened or closed relative to the furnace port.

Preferably, the furnace covers and/or the lower furnace door are/is of a spherical protrusion structure that protrudes downwards.

Further, an inner heating source is arranged on an inner side of the inner furnace tube, while an outer heating source is arranged on an outer side of the outer furnace tube; the inner heating source is divided into a plurality of sets of independent heating sections, and heat dissipation devices are correspondingly arranged on the peripheries of the outer heating source and the inner heating source.

Further, the heat dissipation devices are water-cooling type heat dissipation devices or air-cooling type heat dissipation devices; and water-cooling connectors which are in communication with the water-cooling type heat dissipation devices are arranged on the outer furnace tube, the upper furnace cover, and the lower furnace door.

The present invention also provides a control method for a furnace tube, and the method involves the abovementioned furnace tube and includes the following steps: opening the lower furnace door;
conveying the carriers to the carrier placement positions on the rotating device;
closing the lower furnace door and performing vacuumizing, and adjusting a reaction environment in the sealed chamber; and
controlling the rotating device to drive the carriers on the carrier placement positions to adjust the positions and angles within the sealed chamber.

Further, the adjusting the reaction environment in the sealed chamber specifically includes: starting the heating sources to heat the sealed chamber to reach a preset temperature, and after the sealed chamber reaches the preset temperature, introducing reaction gas into the sealed chamber.

Further, the controlling the rotating device to drive the carriers on the carrier placement positions to adjust the positions and angles within the sealed chamber specifically includes:
driving the carriers on the carrier placement positions to rotate around the inner furnace tube, and adjusting the rotating direction and rotating duration in each rotating direction according to a preset rotating logic.

Further, the opening the lower furnace door is specifically to open small furnace doors on the lower furnace door.

Compared with the existing technology, the present invention have the following advantages:
1. The carriers are placed on the rotatable boat holder base; once the reaction gas is introduced into the sealed chamber or there is a temperature difference during heating, the positions and angles of the carriers in a furnace can be adjusted to make a gas field and a thermal field in the sealed chamber uniform, thereby improving the overall process yield.
2. The inner furnace tube is designed in a through type, thus it can be hoisted from the top or upwards inserted from a bottom support to be mounted, making the mounting mode of the inner furnace tube diversified.
3. The lower furnace door and the upper furnace cover are designed to be convex surfaces that protrude outwards, such that the pressure bearing capacity is improved, and deformation is not prone to occurring.
4. The bottom is sealed using the magnetic fluid assembly, which allows a drive part of the boat holder base to be arranged outside, while ensuring that the sealed chamber in which the reaction gas is introduced is kept sealed.
5. The lower furnace door is provided with a plurality of small furnace doors, and during loading and unloading the carriers, the single small furnace door can be opened, avoiding the loss of heat inside the furnace and affecting processing efficiency.

### BRIEF DESCRIPTION OF THE DRAWINGS

In order to more clearly illustrate the technical solutions in the embodiments of the present invention, the accompanying drawings required for the description of the embodiments or the prior art will be briefly introduced below. It is evident that the accompanying drawings described below are only some embodiments of the present invention, and those of ordinary skill in the art can obtain other drawings based on these accompanying drawings without any inventive effort.

FIG. 1 is a front view according to an Embodiment 1 of the present invention;

FIG. 2 is an A-A sectional view according to an Embodiment 1 of the present invention;

FIG. 3 is a first perspective stereoscopic view according to an Embodiment 1 of the present invention;

FIG. 4 is a top view structural diagram according to an Embodiment 1 of the present invention;

FIG. 5 is a second perspective stereoscopic view according to an Embodiment 1 of the present invention;

FIG. 6 is a front view according to an Embodiment 2 of the present invention;

FIG. 7 is an A-A sectional view according to an Embodiment 2 of the present invention;

FIG. 8 is a top view structural diagram according to an Embodiment 2 of the present invention;

FIG. 9 is a first perspective stereoscopic view according to an Embodiment 2 of the present invention;

FIG. 10 is a second perspective stereoscopic view according to an Embodiment 2 of the present invention;

FIG. 11 is a stereoscopic view of a lower furnace door according to an embodiment of the present invention;

FIG. 12 is a structural diagram of a lower furnace door and a driving structure according to an embodiment of the present invention;

FIG. 13 is a stereoscopic view of a driving structure in match with a furnace cover according to an embodiment of the present invention;

FIG. 14 is a structural diagram of a driving structure in match with a furnace cover according to an embodiment of the present invention;

FIG. 15 is a structural diagram of a driving structure in match with a furnace tube according to an embodiment of the present invention;

FIG. 16 is a front view of a boat holder base according to an Embodiment 1 of the present invention;

FIG. 17 is a structural diagram of a boat holder base according to an Embodiment 2 of the present invention;

FIG. 18 is a stereoscopic view of a boat holder base according to an Embodiment 2 of the present invention;

FIG. 19 is a front schematic diagram of a heating source and a heat dissipation device in match with a furnace tube according to an embodiment of the present invention; and

FIG. 20 is a C-direction view of FIG. 19.

1, furnace tube;
11, outer furnace tube; 111, bracket flange; 112, outer sealing flange; 12, inner furnace tube; 121, inner sealing flange; 122, annular step; 123, annular heat insulation pad; 13, sealed chamber;
2, upper furnace cover;
21, reinforcing rib; 22, lower laminate; 23, inner laminate; 24, outer laminate;
3, lower furnace door;
31, furnace port; 311, first bump; 312, annular cavity;
32, furnace cover; 321, second bump; 322, mounting plate; 323, first guide post; 324, lightening hole;
33, driving structure; 331, rotary driving device; 332, coupling; 333, rotating shaft; 334, rotating plate; 335, push-pull driving device; 336, mounting area; 337, second guide post; 338, first electrical interface; 339, second electrical interface; 340, connecting plate; 341, first partition plate; 342, second partition plate; 343, third partition plate; 344, first accommodating space; 345, second accommodating space;
41, connector; 42, hanging base; 81, top bracket; 82, bottom bracket;
5, boat holder base; 50, carrier; 59, transmission shaft; 591, gear;
51, rotating base; 52, fixing ring; 53, hanging plate; 54, hook hole;
501, carrier placement position; 55, bearing member; 551, fixed bearing part; 552, movable bearing part; 553, rotating shaft;
6, magnetic fluid assembly;
61, outer ring part; 62, inner ring part;
71, outer heating source; 72, inner heating source; 73, heat dissipation device; and 74, water cooling connector.

### DETAILED DESCRIPTION OF SOME EMBODIMENTS

In order to make the technical problems, technical solutions, and beneficial effects to be solved by the present invention clearer, the present invention is described in detail below in combination with the accompanying drawings and embodiments. It is to be understood that the specific embodiments described herein are only used for explaining the present invention and are not intended to limit the present invention.

The principle and structure of the present invention will be described in detail below in conjunction with the accompanying drawings and embodiments.

Existing vertical furnaces are generally provided with inner-outer double-layer furnace tubes, support structures for carriers inside the furnace tubes are fixed and cannot adjusted in positions or angles. This placement way will cause local non-uniformity in a gas field and a thermal field when reaction gases are introduced or there are temperature differences during heating, resulting in poor uniformity and significant differences in process uniformity at the ends and tails of the carrier during decomposition and reaction with the silicon wafer at high temperatures. This affects the overall process yield and causes inconsistency in the quality of cells produced in the same batch.

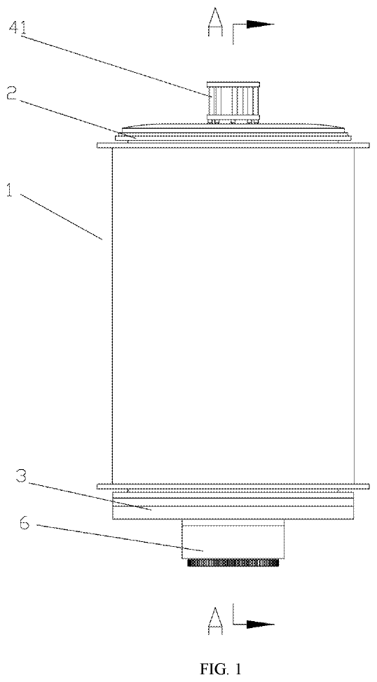

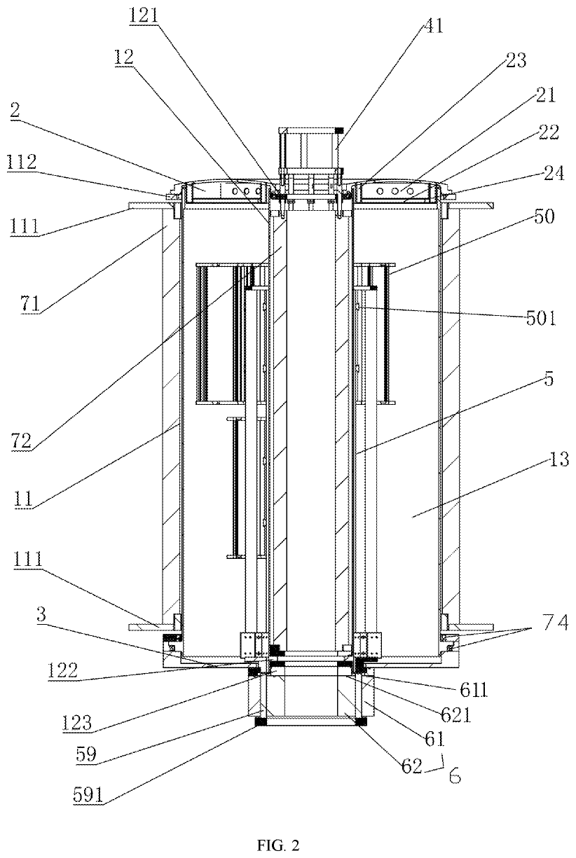

As shown in FIG. 1 and FIG. 2, the present invention provides a furnace tube 1, which includes an outer furnace tube 11, an inner furnace tube 12, an upper furnace cover 2, a lower furnace door 3, and a rotating device, in which,
the inner furnace tube and the outer furnace tube are both in a circular tube shape, an upper end and a lower end of the outer furnace tube 11 are opened, the inner furnace tube 12 is mounted inside the outer furnace tube 11, and an accommodating space is formed between an outer wall of the inner furnace tube 12 and an inner wall of the outer furnace tube after mounting;
the upper end and the lower end of the inner furnace tube 12 are opened, an inner heating source 72 is arranged on the inner side of the inner furnace tube 12, a connecting member used for hoisting connection is arranged at the opening in the upper end of the inner furnace tube 12, and a support platform is arranged at the opening in the lower end of the inner furnace tube 12; and a support base can be mounted on the support platform, such that the inner furnace tube 12 can be hoisted downwards from the top of the outer furnace tube 11 into the outer furnace tube 11 to be mounted, or can be inserted upwards from the bottom of the outer furnace tube 11 into the outer furnace tube 11 to be mounted;
the upper furnace cover 2 and the lower furnace door 3 are correspondingly mounted at the upper ends and lower ends of the outer furnace tube 11 and the inner furnace tube 12, and are used for sealing the upper end and lower end of the accommodating space between the inner furnace tube 12 and the outer furnace tube 11 to form a sealed chamber 13 (a sealing assembly needs to be matched), thus meeting the requirement for vacuumizing in the process; the inner heating source 72 is arranged on an inner side of the inner furnace tube 12, an outer heating source 71 is arranged on an outer side of the outer furnace tube 11, and the inner heating source and the outer heating source can pass through tube walls of the inner furnace tube and the outer furnace tube to heat the interior of the sealed chamber 13 of the furnace tube 1; and
the rotating device is provided with a plurality of carrier placement positions corresponding to the sealed chamber, and the rotating device in rotating is capable of driving the carriers on the carrier placement positions to adjust the positions and angles within the sealed chamber, thereby enabling silicon wafers on the carriers to be heated uniformly.

According to the present invention, the through-type inner furnace tube is arranged, the connecting member is arranged at the opening in the top end of the inner furnace tube, the support platform arranged at the opening in the lower end of the inner furnace tube can be used for mounting the support base, such that the inner furnace tube can be mounted by hoisting from the top or inserting from the bottom of the vertical furnace, making the mounting more convenient; and moreover, the carriers in the furnace tube can be placed on the rotatable rotating device, thus the positions and angles of the carriers can be adjusted in the furnace, and once the reaction gas is introduced into the sealed chamber or there is temperature difference during heating, a gas field and a heat field in the sealed chamber are uniform, thereby improving the overall process yield.

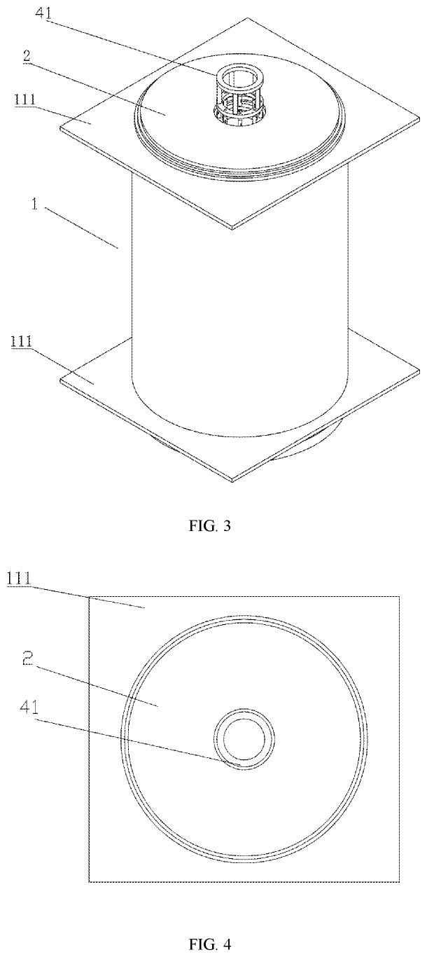

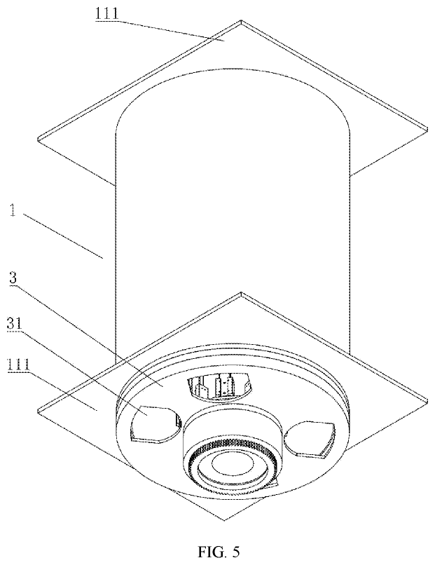

In a specific embodiment, as shown in FIG. 2, the inner wall of the upper end of the inner furnace tube 12 is provided with a circle of support flange (for example, an inner sealing flange 121), the support flange is the connecting member; and the inner furnace tube can be hoisted and fixed in a plurality of modes, and two modes for hoisting and fixing are illustrated below:
in an Embodiment 1, as shown in FIG. 1 to FIG. 5, a connector 41 used for hanging is directly mounted on the support flange (namely the inner sealing flange 121) in a screw connection mode, the connector 41 can be directly connected to a hoisting device, and meanwhile, a screw hole is formed in a support base part at the upper end of the inner heating source 72; a connecting pin of the connector 41 passes through the inner sealing flange 121 to screw in a nut so that the inner sealing flange 121 can be hung on the connecting pin of the connector 14; and moreover, the connecting pin is further in threaded connection with the support base at the upper end of the inner heating source 72, which ensures that the whole inner furnace tube 12 is stably hung.

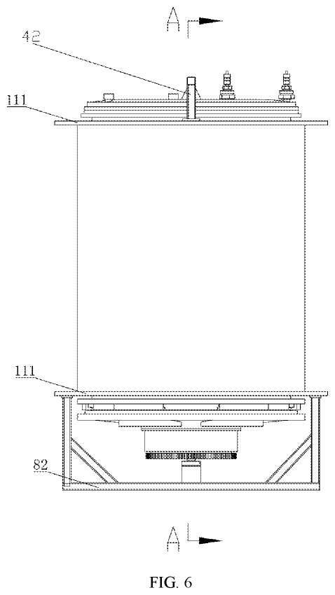

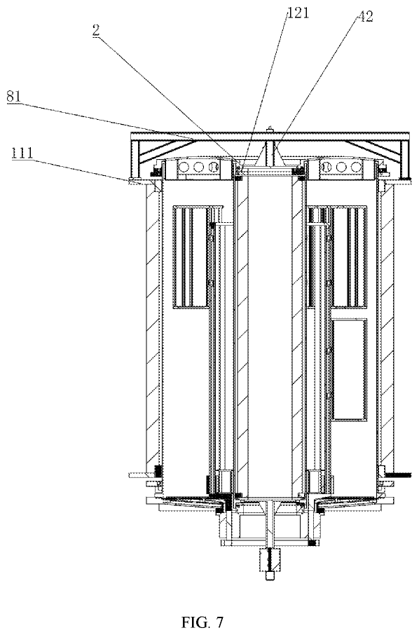

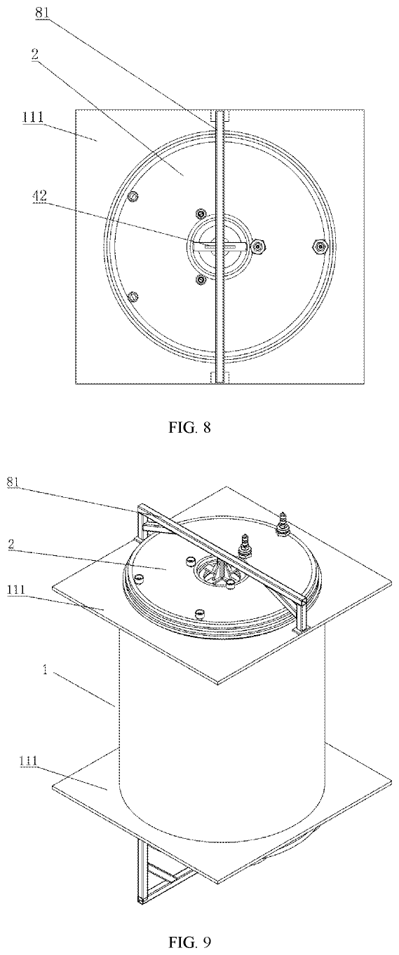

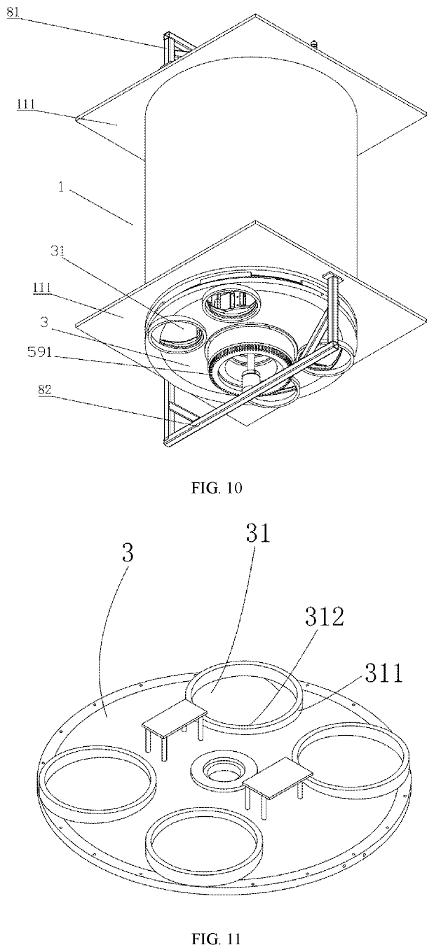

In an Embodiment 2, as shown in FIG. 6 to FIG. 10, a bracket flange 111 is arranged at a position, close to the upper end surface, of the outer wall of the outer furnace tube 11 and is used for mounting a top bracket 81, and a cross beam of the top bracket 81 is hung above the inner furnace tube 12; a hanging base 42 is connected between the cross beam and the support flange (namely the inner sealing flange 121) of the inner furnace tube 12, thus the upper end of the inner furnace tube 12 is directly connected to the top bracket 81 of the furnace tube 1 through the hanging base 42, namely, the inner furnace tube 12 is supported and hung through the build-in flange of the furnace tube 1.

Specifically, the bracket flange 111 is also arranged at the position, close to the lower end surface, of the outer wall of the outer furnace tube 11 and used for mounting a bottom bracket 82, and the bottom bracket 82 can be used for assisting in fixing peripheral parts of the furnace tube, such as a water cooling pipeline, playing a role of supporting the whole furnace tube.

In a specific embodiment, the support platform at the lower end of the inner furnace tube 12 can also be arranged in a plurality of modes, and two modes are illustrated below:
in the Embodiment 1, as shown in FIG. 2, a circle of annular step 122 protrudes out of the inner wall of the lower end of the inner furnace tube 12, and the lower side surface of the annular step 122 can be used as the support platform for mounting or connecting the support base through which the bottom of the inner furnace tube can be stably placed.

In the Embodiment 2, the inner wall of the inner furnace tube 12 close to the lower end surface is provided with a circle of support flange (not shown in the figure), and the support base is connected through the support flange so that the bottom of the inner furnace tube can be supported.

As shown in FIG. 2, the annular step or support flange can be equipped with an annular heat insulation pad 123 that can be used as the support base, and meanwhile, the lower end surface of the annular heat insulation pad 123 exceeds the lower end of the inner furnace tube 12, achieving the supporting effect as well as the heat insulation effect.

Specifically, the annular heat insulation pad 123 is fixedly connected to the annular step or support flange of the inner furnace tube 12 in a sealed connection mode, namely, the joint between the annular heat insulation pad 123 and the inner furnace tube is in a sealed state.

In a specific embodiment, as shown in FIG. 2, central holes are formed in the middles of both the upper furnace cover 2 and the lower furnace door 3, and the central hole in the upper furnace cover can pass through the upper end of the inner furnace tube 12 or pass through a hanging member (such as the connector and the hanging base) that is connected to the upper end of the inner furnace tube; and the central hole in the lower furnace door 3 can pass through the lower end of the inner furnace tube 12.

As shown in FIG. 2, the specific embodiments of the structure and sealed connection of the upper furnace cover 2 are as follows:
the outer end surface of the upper furnace cover 2 away from the sealed chamber 13 protrudes outwards to form a spherical protrusion. As the sealed chamber 13 needs to be vacuumized, the outer end surface of the upper furnace cover is arranged to form the spherical protrusion that protrudes upwards, which can bear higher pressure and prevent the interior from being sucked in and deformed when vacuumizing.

A lower laminate 22, an outer laminate 24, and an inner laminate 23 which are matched with the inner side of the outer end surface to define the cavity are also arranged in the upper furnace cover 2; the lower laminate 22, the outer laminate 24, and the inner laminate 23 are all annular and define an annular cavity in the inner side of the outer end surface of the upper furnace cover 2, and a plurality of reinforcing ribs 21 are arranged in the annular cavity, specifically between the upper inner wall and the lower inner wall of the cavity; the reinforcing ribs 21 are plate-shaped, and a plurality of through holes are formed in the plate surfaces; and the reinforcing ribs 21 are annularly arranged at intervals in the annular cavity.

Preferably, the lower laminate 22, the outer laminate 24, and the inner laminate 23 are hollow laminates; the interiors of the hollow laminates can be used as water cooling channels or used for mounting the water cooling assemblies such as the water cooling pipeline, thereby preventing heat from dissipating from the upper furnace cover to influence processing.

As shown in FIG. 2, the specific embodiment of the sealing mode for the top of the furnace tube is as follows:
an outer sealing flange 112 (located above the bracket flange) is arranged on the outer wall of the upper end of the outer furnace tube 11, and an inner sealing flange 121 (also used as the connecting member for realizing sealed connection with the upper furnace cover and implementing hanging connection) is arranged on the inner wall of the inner furnace tube 12; the upper furnace cover 2 covers the upper end surfaces of the outer furnace tube and the inner furnace tube, and the central hole is formed in the middle of the upper furnace cover 2, namely the whole upper furnace cover 2 is annular; the outer edge of the upper furnace cover 2 is buckled with the upper end surface of the outer furnace tube 11 and is in sealed connection with the outer sealing flange 112 of the outer furnace tube 11, and the inner edge of the upper furnace cover 2 is buckled with the upper end of the inner furnace tube 12 and is in sealed connection with the inner sealing flange 121 of the inner furnace tube 12.

It is to be noted that the inner sealing flange is also used as the support flange, namely the inner sealing flange is used as the connecting member; the part of the inner sealing flange close to the tube wall of the inner furnace tube is in sealed connection with the upper furnace cover, and the part of the inner sealing flange close to the center of the inner furnace tube can pass through the connecting pin of the connector or the hoisting base.

Specifically, the mode for sealed connection of the inner sealing flange and outer sealing flange with the upper furnace cover is a conventional sealing means in the existing technology, for example, it may also require the use of screws, gaskets, sealing rings, etc., which can be fully reproduced by those skilled in the art, and will not be repeated in the present invention.

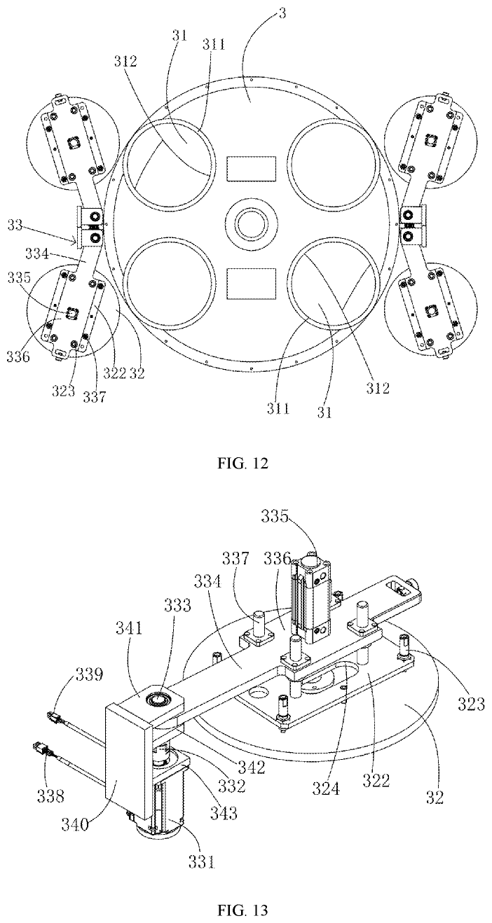

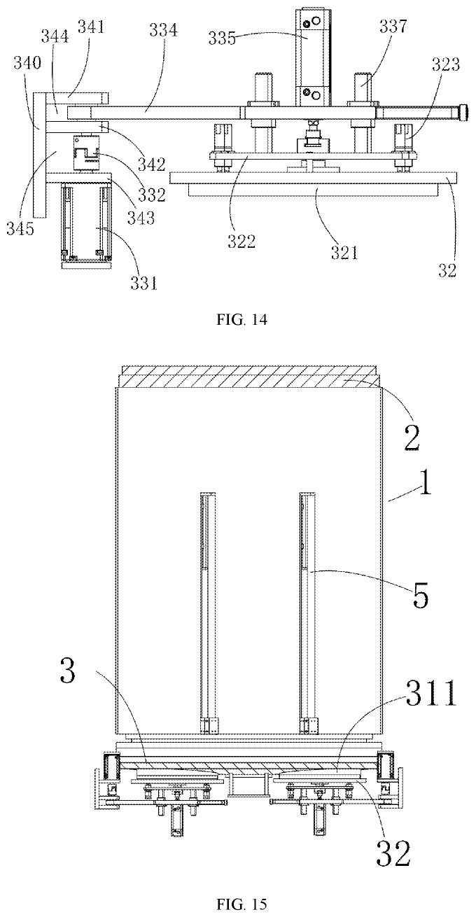

Specifically, as shown in FIG. 11 to FIG. 15, the specific embodiments of the structure of the lower furnace door are as follows:
in the Embodiment 1, the lower furnace door 3 is integral, with the central hole in the middle; and during opening, and the whole lower furnace door is opened directly.

The lower furnace door 3 protrudes downwards to form a drum surface, namely a spherical protrusion structure. The lower furnace door can bear higher pressure like the upper furnace cover.

In the Embodiment 2, the central hole is formed in the middle of the lower furnace door 3; a plurality of small furnace doors, namely furnace ports 31, and furnace covers 32 corresponding to the small furnace doors are arranged on the lower furnace door; the furnace ports 31 are matched with the side surfaces of the carriers in size and shape, specifically, the shapes of the furnace ports 31 can be consistent with those of the side surfaces of the carriers, and the sizes of the furnace ports 31 can be slightly larger than those of the side surfaces of the carriers, such that the carriers can just pass through the furnace ports 31; the furnace covers 32 are connected to driving structures 33, the driving structures 33 are used for driving the furnace covers 32 to be opened or closed relative to the furnace ports 31, and therefore, the small furnace doors can be individually, reducing the heat loss in the furnace tube.

In the embodiment, the lower furnace door 3 and the furnace covers 32 are preferably of the spherical protrusion structures that protrude downwards. Therefore, the lower furnace door and the furnace covers can bear higher pressure to prevent from being sucked in to damage the lower furnace door when vacuumizing in the sealed space within the furnace tube.

In order to enable the furnace covers 32 to fit more closely with the corresponding furnace ports 31, improve the sealing property, and reduce the heat loss in the furnace tube, first bumps 311 are arranged on the sides of the furnace ports 31 facing the furnace covers 32 and surround the furnace ports 31 in the circumferential direction to form annular cavities 312; and the furnace ports 31 are completely located in the annular cavities 312.

Second bumps 321 are arranged on the sides, facing the furnace ports 31, of the furnace covers 32 matched with the furnace ports 31, and the second bumps 321 can be inserted into the annular cavities 312 in a matched mode. In order to further improve the sealing property between the furnace covers 132 and the corresponding furnace ports 31, high-temperature-resistant sealing strips can further be arranged on the second bumps 321 in a surrounding mode.

Specifically, the driving structures 33 include rotary driving devices 331, couplings 332, rotating shafts 333, rotating plates 334, push-pull driving devices 335, and connecting plates 340;
in which, the rotary driving devices 331 are preferably rotating motors, and the push-pull driving devices 335 are preferably push-pull motors.

One side of the lower furnace door 3 is provided with the rotary driving device 331 corresponding to each furnace port 31, the rotating end of each rotary driving device 331 is connected to the corresponding rotating shaft 333 through the corresponding coupling 332, a tail end of each rotating shaft 333 is connected to the corresponding rotatable rotating plate 334, and each rotating plate 334 is located in front of the corresponding furnace port 31; the rotating ends of the rotary driving devices 331 can be firmly connected to the rotating shafts 333 through the couplings 332, such that the rotating ends of the rotary driving devices 331 can rotate together with the rotating shafts 333 and transfer torque and motion, and therefore it is guaranteed that during the process of transferring the motion and power, relative positions between the rotating ends of the rotary driving devices 331 and the rotating shafts 333 are kept unchanged, thus realizing reliable transmission; the couplings 332 can also compensate for displacement of the rotating ends of the rotary driving devices 331 and the rotating shafts 333, thus ensuring the continuity and stability of transmission; and the couplings 332 can also buffer impact and absorb vibration, thereby reducing the abrasion and fault risks of the rotating ends of the rotary driving devices 331 and the rotating shafts 333, and improving the stability and reliability of the driving structures 33.

The push-pull driving devices 335 are connected to the middles of the rotating plates 334 by bolts, and push-pull ends of the push-pull driving devices 335 pass through the rotating plates 334 and are connected to the furnace covers 32.

Specifically, each driving structure 33 further includes a first partition plate 341 and a second partition plate 342 which are arranged at intervals on one end of the corresponding connecting plate 340, and a third partition plate 343 is arranged on the other end of the connecting plate 340; a first accommodating space 344 is formed among the first partition plate 341, the second partition plate 342, and the corresponding part of the connecting plate 340; a second accommodating space 345 is formed among the second partition plate 342, the third partition plate 343, and the corresponding part of the connecting plate 340; and through holes (not shown, same throughout) are formed in the same positions on the first partition plate 341, the second partition plate 342, and the third partition plate 343. Each rotary driving device 331 is fixed to the side of the third partition plate 343 away from the second partition plate 342, then the rotating end of the rotary driving device 331 passes the through hole in the third partition plate 343 to be connected to the corresponding coupling 332, and the coupling 332 is located in the second accommodating space 345; one end of each rotating shaft 333 is rotationally connected into the through hole in the first partition plate 341 while the other end thereof passes through the through hole in the second partition plate 342 to be connected to the corresponding coupling 332, and each rotating plate 334 sleeves the rotating shaft 333 located in the first accommodating space 344. In this way, the first accommodating space 344 and the second accommodating space 345 can effectively isolate the space between each coupling 332 and the corresponding rotating shaft 333 that is sleeved with the rotating plate 334, such that accidental contact caused by mechanical faults or improper operation can be prevented, the potential injury risk can be reduced, and the safety of workers and device can be protected; and by the first accommodating space 344 and the second accommodating space 345, the mutual influence between each coupling 332 and the corresponding rotating shaft 333 that is sleeved with the rotating plate 334 can be reduced, vibration and force produced by each rotary driving device 331 in operation can be prevented from being transferred between the coupling 332 and the rotating shaft 333 that is sleeved with the rotating plate 334, thereby improving the stability of the whole driving structure 33.

The lower furnace door further includes a control unit; the rotary driving devices 331 are provided with first electrical interfaces 338; the push-pull driving devices 335 are provided with second electrical interfaces 139; and both the first electrical interfaces 338 and the second electrical interfaces 339 are electrically connected to the control unit for controlling the furnace door structure.

In this way, if it is needed to open the furnace covers 32 relative to the furnace ports 31, an operator clicks start on a corresponding operation panel of the control unit; after the control unit receives an open signal from the operation panel, the push-pull driving devices 335 will be started firstly to control the furnace covers 32 to be away from the corresponding furnace ports 31 until the furnace covers 32 do not make contact with the corresponding furnace ports 31, then a control center stops the push-pull driving devices 335 and simultaneously starts the rotary driving devices 331, and at the moment, the rotary driving devices 331 control the rotating plates 334 and the furnace covers 32 on the rotating plates 334 to move towards the outer side away from the centers of the furnace covers 32, such that the corresponding furnace ports 31 can be completely exposed; then the control unit stops the rotary driving devices 331, the operator inserts the carrier carrying wafers to be processed into the furnace ports 31 and then places into the furnace tube 1, after which the process is carried out, specifically, specific reaction gas is introduced into the furnace tube 1 to perform specific processes on the wafer to be processed, such as coating, diffusion, oxidation, and thin-film deposition.

If it is needed to close the furnace covers 32 relative to the furnace ports 31, the operator clicks stop on the corresponding operation panel of the control unit; then after the control unit receives a stop signal from the operation panel, the control unit starts the rotary driving device s331 firstly to control the rotating plates 334 and the furnace covers 32 on the rotating plates 334 to move towards the inner side away from the circle centers of the furnace covers 32 for resetting; then the control center stops the rotary driving devices 331 and simultaneously starts the push-pull driving devices 335 to control the furnace covers 32 to get close to the corresponding furnace ports 31 till the second bumps 321 of the furnace covers 32 are inserted into the annular cavities 312 of the corresponding furnace ports 31 in a matched manner, such that the furnace covers 32 can completely cover the corresponding furnace ports 31; and then the control unit stops the push-pull driving devices 335.

Rectangular mounting plates 322 are further arranged on the sides of the furnace covers 32 facing the rotating plates 334; the push-pull ends of the push-pull driving devices 335 are connected to the middles of the mounting plates 322, and the peripheries of the mounting plates 322 are connected to the furnace covers 32 through first guide posts 323. The mounting plates 322 can share part of weight and loads between the furnace covers 32 and the push-pull driving devices 335, thereby improving the stability and reliability of the whole structure; moreover, the mounting plates 322 can further absorb vibration and impact force by the furnace covers 32 during rotating, thus reducing the damage to the furnace covers 32 and the push-pull driving devices 335, and prolonging the service lives thereof; and the mounting plates 322 can be connected to the furnace covers 32 through the first guide posts 323, therefore the relative position between the furnace covers 32 and the push-pull driving devices 335 can be better adjusted, ensuring the accuracy and stability of the furnace covers 32 in rotating.

A plurality of lightening holes 324 are formed in the mounting plates 322, and the lightening holes 324 are capable of lightening the mounting plates 322 so that the rotary driving devices 331 and the push-pull driving devices 335 can better control the movement of the furnace covers 32.

Rectangular mounting areas 336 are arranged in the middles of the rotating plates 334, the push-pull driving devices 335 are arranged in the middles of the mounting areas 336, and the peripheries of the mounting areas 336 are connected to the mounting plates 322 through second guide posts 337.

In this embodiment, that the second guide posts 337 are mounted at four corners of the mounting areas 336 is taken as an example for illustrating.

By the second guide posts 337, the relative position between the mounting plates 322 and the furnace covers 32 can be kept in accurate alignment, therefore, during the rotating process of the furnace covers 32, the mounting plates 322 and the furnace covers 32 can be guided by the second guide posts 337 to move along a predetermined path and are prevented from deviating from correct positions or displacing, which is conducive to keeping the stability and accuracy of the furnace covers 32 in rotating.

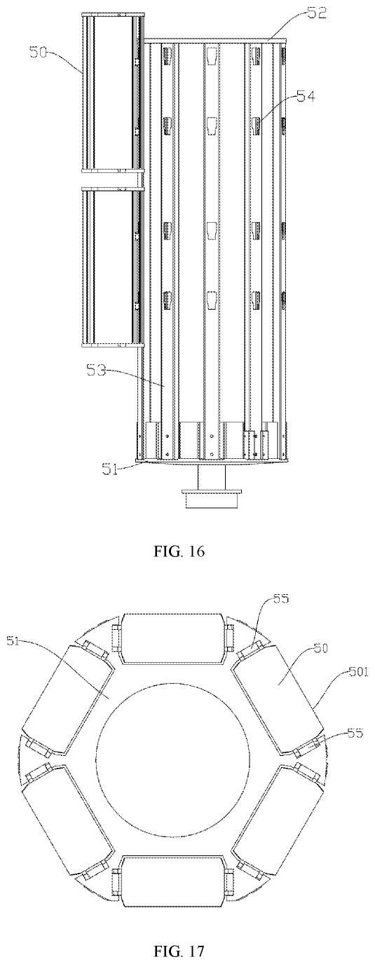

As shown in FIG. 2 and FIG. 16, in a specific embodiment, a magnetic fluid sealing assembly is in sealed connection with the central hole in the lower furnace door and is used for rotary sealing of the rotating device.

Further, the rotary sealing rotating device specifically includes: a boat holder base and a rotating power source. The boat holder base is arranged in the sealed chamber of the furnace tube and is provided with the plurality of carrier placement positions, and the inner edge of the bottom of the boat holder base protrudes downwards by a circle to be connected to the transmission shaft of the magnetic fluid sealing assembly, such that if the rotating shaft rotates, the boat holder base follows the rotation; the rotating power source is directly connected to the lower end, located outside the sealed chamber of the furnace tube, of the transmission shaft of the magnetic fluid sealing assembly; a power source is provided outside the furnace tube to avoid high temperature inside the furnace affecting the normal operation of the rotating power source, it is because the temperature inside the furnace tube is about 500°or higher, and at this temperature, the motor serving as the rotating power source cannot operate normally; and placing the rotating power source externally can ensure the normal operation of the rotating device.

By the rotatable boat holder base 5, the positions and angles of the carriers can be adjusted; therefore, once the reaction gas is introduced into the sealed chamber or there is temperature difference during heating, the gas field and heat field in the sealed chamber are uniform, thereby improving the overall process yield.

Specifically, as shown in FIG. 2, the magnetic fluid assembly 6 is located at the bottom of the furnace tube 1 and specifically includes an annular outer ring part 61, an inner ring part 62, and a transmission shaft 59; the top surface of the outer ring part 61 is in sealed connection with the edge of the central hole in the lower furnace door 3, and a first sealing ring 611 can be seen in the figure; the top surface of the inner ring part 62 is in sealed connection with the lower end surface of the annular heat insulation pad 123 at the bottom of the inner furnace tube 12, and the second sealing ring 621 can be seen in the figure; a gap between the inner ring part 62 and the outer ring part 61 of the magnetic fluid assembly 6 forms a circle of annular rotary sealing space, and the transmission shaft 59 passes through the rotary sealing space of the magnetic fluid assembly 6.

The inner side of the boat holder base 5 surrounds the inner furnace tube 12 and is provided with the plurality of carrier placement positions 501, and the rotating base 51 at the bottom is annular and passes through the central hole in the lower furnace door; the annular transmission shaft 59 is connected to the lower part of the rotating base 51, the upper end of the transmission shaft 59 is connected to the bottom of the rotating base 51 and passes through the rotary sealing space of the magnetic fluid assembly 6; the lower end of the transmission shaft 59 is located outside the furnace tube, while the lower end thereof is provided with a gear or a belt wheel rotationally connected to the rotating power source. Therefore, the whole boat holder base 5 can be driven by the rotating power source through the transmission shaft 59 to rotate around the inner furnace tube 12.

A magnetic fluid (not shown in the figure) is arranged in the gap between the inner wall surface of the transmission shaft 59 and the outer wall surface of the inner ring part 62 of the magnetic fluid assembly, specifically, a plurality of circles of annular grooves for accommodating the magnetic fluid can be arranged in the inner wall surface of the transmission shaft 59 or arranged in the outer wall surface of the inner ring part of the magnetic fluid assembly, thus a plurality of circles of sealing rings located in the gap between the inner wall surface of the transmission shaft 59 and the outer wall surface of the inner ring part 62 of the magnetic fluid assembly 6 are formed;
the magnetic fluids are arranged on the outer wall surface of the transmission shaft and the inner wall surface of the outer ring part of the magnetic fluid assembly in the same way, permanent magnets are arranged in both the outer ring part 61 and the inner ring part 62, and magnetic poles are used as the inner wall of the rotary sealing space, thus the magnetic fluid can surround the transmission shaft 59 and form the plurality of circles of sealing rings located in the gap between the outer wall surface of the transmission shaft and the inner wall surface of the outer ring part of the magnetic fluid assembly.

Specifically, the outer edge of the lower furnace door 3 is connected to the step at the bottom of the outer furnace tube 11, and the inner edge of the lower furnace door 3 is in sealed connection with the outer ring part 61 of the magnetic fluid assembly 6, namely, the annular heat insulation pad (support base) at the bottom of the inner furnace tube, the inner edge of the lower furnace door, and the transmission shaft (tubular or called as a transmission tube) passing through the magnetic fluid assembly are directly in sealed connection through the magnetic fluid assembly, thus sealing the lower end of the sealed chamber 13 in the furnace tube 1.

In the specific embodiment, the outer wall surface of the transmission shaft 59 penetrating out of the rotary sealing space of the magnetic fluid assembly 6 is provided with a circle of gears 591, and the rotating power source drives the internal boat holder base to rotate through the transmission of external motor gears.

In other embodiments, the outer wall surface of the transmission shaft penetrating out of the rotary sealing space of the magnetic fluid assembly is sleeved with a belt pulley, and the rotating power source drives the transmission shaft to perform transmission through the belt pulley.

FIG. 16 shows the Embodiment 1 of the boat holder base, the boat holder base includes: a rotating base 51, a fixing ring 52, and hanging plates 53, in which,
the rotating base 51 is in a disc shape, a plurality of hanging plates are vertically arranged at intervals in a circle along the annular edge of the upper surface of the base, the fixing ring 52 is connected to the tops of the hanging plates 53 so that the tops of the hanging plates 53 are fixed and the hanging plates 53 are a stable vertical state; a plurality of hanging positions (namely carrier placement positions) for hanging the carriers are arranged at intervals on the outer side surfaces of the hanging plates 53 in the length direction, namely, a plurality of carriers 50 can be hung on the hanging plates 53 in the height direction, specifically, the carriers 50 can be hung at different heights of the boat holder base, and the carriers can be hung in a plurality of layers in the height direction of the whole boat holder base;
the annular transmission shaft 59 is connected in a circle along the inner edge of the rotating base 51, thus the rotating base 51 can be supported, and the rotating base 51 can be driven to rotate using the center of the rotating base 51 as the central axis; during rotating the rotating base 51, the carriers 50 located on the outer side surfaces of the hanging plates 53 follow the rotation of the rotating base 51 around the central axis of the center of the base, and thus the positions and angles of the carriers can be changed during processing.

In the specific embodiment, hook holes 54 for hanging the carriers are formed in the hanging positions of the hanging plates 53, and the hook holes 54 are wide in upper parts and narrow in lower parts, facilitating the hooks of the carriers to hang in;
the carriers 50 are vertical quartz boats and equipped with the hooks that can be downwards clamped into the hook holes; and after the hooks of the vertical quartz boats are clamped into the hook holes, the vertical quartz boats can be hung at the hanging positions.

Specifically, two hooks are arranged on the side surface of each vertical quartz boat in the height direction, and one vertical quartz boat is hung on every two hook holes in the hanging plates; in this embodiment, two vertical quartz boats can be hung on each hanging plate 53 in the height direction, and the quartz boats can be arranged into an upper circle and a lower circle around the boat holder base; and therefore, the plurality of vertical quartz boats hung on the boat holder base can be heated in a plurality of modes such as layered heating, local heating, and integral heating.

Specifically, the rotating base 51 can further be provided with a heat shield (not shown in the figure), the heat shield is provided with a plurality of through holes through which the hanging plates can pass; a water cooling assembly is arranged in the heat shield (a specific water cooling source can be provided through a water cooling connector at the lower furnace cover); the heat shield does not influence the rotation of the rotating base 51 and the hanging of the carriers on the hanging plates and can prevent the position temperature of the rotary base from becoming too high to affect the stability.

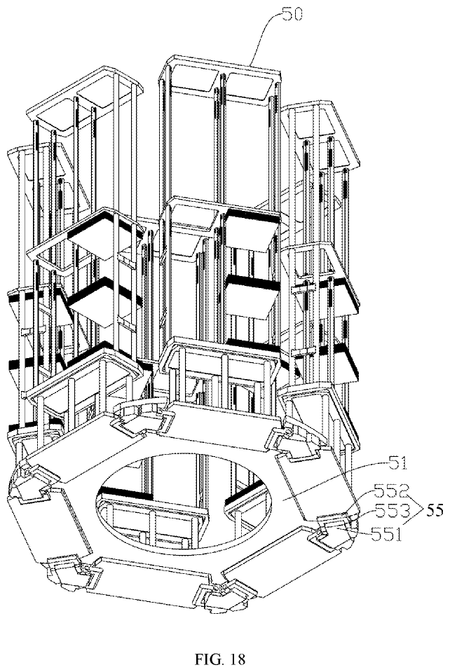

As shown in FIG. 17 and FIG. 18, in the Embodiment 2 of the boat holder base, the boat holder base includes: the rotating base 51 and a plurality of pairs of bearing members 55. The rotating base 51 is provided with the plurality of carrier placement positions 501 through which the carrier boats can pass or be placed; each pair of bearing members 55 is located on the edges of both sides of one carrier placement position 501 and can be arranged on the rotating base 51 in a foldable mode. Moreover, each pair of bearing members 55 has a folded state and an unfolded state; if it is needed to place the carriers 50, each pair of bearing members 55 is switched into the folded state, then the carriers 50 can upwards pass through the carrier placement positions 501 from bottom; if the bottoms of the carriers 50 move above the horizontal planes of the carrier placement positions 501, each pair of bearing members 55 is switched into the unfolded state, then the carriers 50 are placed on the bearing members; if it is needed to take out the carriers 50, each pair of bearing members 55 is switched into the folded state, then the carriers 50 can pass through the carrier placement positions 501 downwards to be taken out of the furnace door; and therefore, the taking-out and placing of the carriers are implemented.

In each pair of bearing members 55, each bearing member 55 includes a fixed bearing part 551 and a movable bearing part 552, the fixed bearing part 551 is fixedly arranged on the rotating base 51, and the movable bearing part 552 is rotationally arranged on the fixed bearing part 551. In each bearing member 55, the rotating shaft 553 is arranged on the fixed bearing part, the movable bearing part 552 includes two opposite first bearing rods and second bearing rods connected to the two first bearing rods, and the ends of the two bearing rods away from the second bearing rods sleeve the two ends of the rotating shaft. It is to be understood that the rotating base further includes a driving member (not shown in the figure) that is used for driving the rotating shaft to rotate, and the driving member can be a motor. A self-locking supporting structure is also included and used for self-locking of the motor for example (not shown in the figure), and the self-locking supporting structure is used for limiting the rotating angle of the movable bearing part.

If each pair of bearing members 55 is in the folded state, the movable bearing part 552 in each bearing member 55 is arranged away from the corresponding carrier placement position 501; and if each pair of bearing members 55 is in the unfolded state, the movable bearing part 552 in each bearing member 55 is arranged towards the corresponding carrier placement position and abuts against the corresponding carrier.

By taking the rotating angle of the movable bearing part in each bearing member 55 being 90° as an example, if each pair of bearing members 55 is in the folded state, the movable bearing part 552 in each bearing member 55 is in a vertical state, and at the moment, the movable bearing part 552 in each bearing member 55 cannot shield the carrier placement position 501 at the rotating base 51, and therefore up-down movement of the carrier boat cannot be interfered. If each pair of bearing members is in the unfolded state, the movable bearing part in each bearing member is in a horizontal state, and at the moment, the movable bearing part in each bearing member extends into the carrier placement position at the rotating base, and therefore the carrier boat can be supported.

In this embodiment, in any two adjacent pairs of bearing parts, the bearing fixing part of one pair of bearing parts is connected to the bearing fixing part of the other pair of bearing parts. In practical application, in any two adjacent pairs of bearing parts, two interconnected bearing fixing parts can be integrally formed. By means of such design, the number of spare parts can be decreased, and the time for mounting is also saved.

In this embodiment, the carrier placement positions 501 are gaps formed in the rotating base 51. The carrier placement positions 501 are matched with the carrier boats in shape and size, such that the carrier boats can smoothly pass through the carrier placement positions. It is to be understood that in other embodiments, the carrier placement positions can be the through holes formed in the rotating base.

As shown in FIG. 18, the carriers can be stacked in the height direction, namely, a plurality of carriers can be placed on one carrier placement position; meanwhile, in order to prevent the carriers from toppling, a circle of vertical guardrail can be arranged along the outer edge of the rotating base; and as the inner edge of the rotating base is close to the outer wall of the inner furnace tube, the stacked carriers can be prevented from toppling through the outer wall of the inner furnace tube and the guardrail.

In the specific embodiment, the external heating source and the internal heating source are integrated, namely, electric heating wires are wound directly onto the inner furnace tube and outer furnace tube to directly heat the sealed chamber.

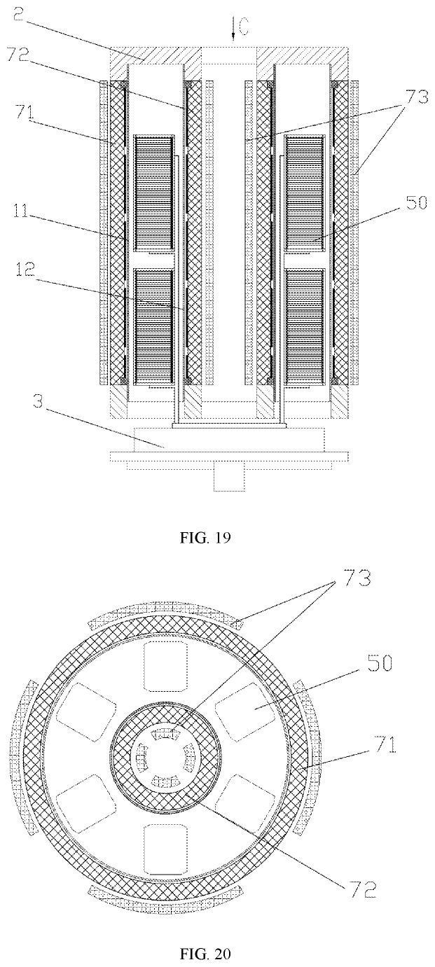

In the preferred embodiments as shown in FIG. 19 and FIG. 20, the external heating source 71 and the internal heating source 72 are both arranged annularly and are distributed in the height direction of the internal furnace tube and the external furnace tube, specifically, the external heating source 71 and the internal heating source 72 can be divided into a plurality of sets of independent heating sections in the height direction of the furnace tubes, and the carriers can be correspondingly hung by layers on the boat holder base in the height direction, such that the heating is correspondingly carried out by layers, thereby improving the overall heating efficiency.

As an alternative embodiment, the external heating source and the internal heating source are divided into the plurality of sets of independent heating sections which are arranged at intervals around the internal furnace tube and the external furnace tube.

Specifically, the internal heating source and the external heating source can be used for heating the furnace tubes by resistance wires, or by means of infrared heating, electromagnetic induction heating, and the like.

In a further embodiment, the peripheries of the external heating source and the internal heating source are provided with heat dissipation devices 73 for quickly and stably adjusting the temperature of the reaction furnace tubes. The heat dissipation devices can be independent or integrated with the heating device. The heat dissipation devices can be manually controlled or automatically controlled by acquiring temperature signals, pressure signals and the like, and any mode that can realize automatic control is included in this scope. The heat dissipation devices 73 can be of air cooling structures or water cooling structures. But the heat dissipation devices 73 are not limited to the structures above, and any mechanism with the heat exchange and heat dissipation function is included within this scope.

Specifically, in FIG. 2, water cooling connectors 74 are arranged on the end surfaces of the external furnace tube 11, the upper furnace cover 2, and the lower furnace door 3 and are used for supplying water to the heat dissipation devices inside.

As shown in the figure, water slide ring is arranged in the bottom bracket at the bottom of the furnace tube and is used for supplying water to the water cooling pipeline (not shown in the figure).

In the specific embodiment, the internal furnace tube and the external furnace tube are specifically quartz tubes, or silicon nitride tubes. According to the furnace tube provided by the present invention, the inner furnace tube is designed in a through type, thus the inner furnace tube can be hoisted from the top or upwards inserted from the bottom support to be mounted, making the mounting mode of the inner furnace tube diversified.

The carriers in the furnace tube are placed on the rotatable boat holder base, so that the positions and angles of the carriers can be adjusted in the furnace; and once the reaction gas is introduced into the sealed chamber or there is temperature difference during heating, the gas field and heat field in the sealed chamber are uniform, thereby improving the overall process yield.

The lower furnace door and the upper furnace cover are designed to be drum surfaces that protrude outwards, such that the pressure bearing capacity is improved, and deformation is not prone to occurring.

The bottom is sealed by the magnetic fluid assembly, which allows a drive part of the boat holder base to be arranged outside, while ensuring that the sealed chamber through which the reaction gas is introduced is kept sealed.

The lower furnace door is provided with a plurality of small furnace doors; and during loading and unloading the carrier, the small furnace doors can be opened individually, avoiding the loss of heat inside the furnace and affecting processing efficiency.

A control method for the furnace tube provided by the present includes the following specific steps:
opening the lower furnace door;
conveying the carriers to the carrier placement positions on the rotating device;
closing the lower furnace door and performing vacuumizing, and adjusting a reaction environment in the sealed chamber; and
controlling the rotating device to drive the carriers on the carrier placement positions to adjust the positions and angles within the sealed chamber.

By controlling the rotating of the rotating device, the carriers can follow rotation in the sealed chamber, therefore, once the reaction gas is introduced into the sealed chamber or there is temperature difference during heating, the gas field and heat field in the sealed chamber are uniform, thereby improving the overall process yield.

Specifically, the adjusting the reaction environment in the sealed chamber specifically includes: starting the heating sources to heat the sealed chamber to reach a preset temperature, and after the sealed chamber reaches the preset temperature, introducing reaction gas into the sealed chamber.

The controlling the rotating device to drive the carriers on the carrier placement positions to adjust the positions and angles within the sealed chamber specifically includes:
driving the carriers on the carrier placement positions to rotate around the inner furnace tube, and adjusting the rotating direction and rotating duration in each rotating direction according to a preset rotating logic.

There are a plurality of embodiments provided for specific rotation, specifically, the rotation can be a 360° circular motion in a clockwise or anticlockwise way; or the rotation is a reciprocating motion carried out clockwise by a certain angle, then counterclockwise by a certain angle.

Specifically, the opening the lower furnace door is specifically to open the small furnace doors on the lower furnace door to avoid temperature loss in the furnace.

According to the boat holder base of the rotating device in the Embodiment 1, the carriers are conveyed into the sealed chamber from the small furnace doors using an automatic device (such as a mechanical arm or a special manipulator), and are then hung on the boat holder base; and the operation is carried out until all the carriers are hung in sequence.

According to the boat holder base of the rotating device in the Embodiment 2, the carriers are conveyed into the sealed chamber from the small furnace doors using the automatic device (such as the mechanical arm or the special manipulator); during this process, bearing blocks are in the folded state; and after the automatic device moves out of the sealed chamber, the bearing blocks are in the unfolded state to bear the carriers.

It is to be noted that the terms used above are only to describe specific implementations and are not intended to limit the exemplary embodiments of the present invention. As used herein, unless the context otherwise clearly indicates, the singular form is also intended to include the plural form. In addition, it is to be understood that when the terms “include” and/or “comprise” are used in this specification, they specify the presence of features, steps, operations, devices, components, and/or their combinations.

Unless otherwise specifically stated, the relative arrangement, numerical expressions, and values of the components and steps described in these embodiments do not limit the scope of the present invention. It is also to be understood that, for the sake of convenience in description, the sizes of the various parts shown in the accompanying drawings are not drawn to scale. Technologies, methods, and devices known to those of ordinary skill in the relevant field may not be discussed in detail, but, where appropriate, such technologies, methods, and devices should be considered part of the authorized specification. In all examples shown and discussed herein, any specific values should be interpreted merely as illustrative, not as limiting. Therefore, other examples of the exemplary embodiments may have different values. It is to be noted that: similar reference numbers and letters in the following accompanying drawings indicate similar items, so once an item is defined in one drawing, it does not need further discussion in subsequent accompanying drawings.

In the description of the present invention, it is to be understood that directional terms such as “front, back, top, bottom, left, and right”, “horizontal, vertical, perpendicular, and level”, and “upper and lower” as indicated in orientation or positional relationships are generally based on the orientation or positional relationships shown in the accompanying drawings and are only intended to facilitate the description of the present invention and to simplify the description. Unless otherwise specified, these directional terms do not indicate or imply that the referenced device or element must have a specific orientation or be constructed and operated in a specific orientation, and should not be understood as limiting the scope of protection of the present invention. The terms “inner” and “outer” refer to the inside and outside relative to the contour of each component itself.

For ease of description, spatial relative terms such as “above . . . ”, “over . . . ”, “on the upper surface of . . . ”, “on top of . . . ”, etc., can be used here for describing the spatial positional relationships of a device or feature with other devices or features as shown in the figures. It is to be understood that the purpose of spatial relative terms is to include different orientations during use or operation other than the orientation of the device as depicted in the figures. For example, if a device in the accompanying drawings is inverted, the device previously described as “over other devices or structures” or “above other devices or structures” would then be positioned “under other devices or structures” or “below other devices or structures.” Therefore, exemplary terms such as “over . . . ” can include both “over . . . ” and “under . . . ” orientations. The device may also be positioned in other different ways (rotated 90° or in other orientations), and the spatial relative descriptions used herein should be interpreted accordingly.

The above description is only a preferred embodiment of the present invention and is not intended to limit the present invention. For those skilled in the art, various changes and modifications can be made to the present invention. Any modifications, equivalent substitutions, improvements, etc., made within the spirit and principles of the present invention should be included within the scope of protection of the present invention.

What is claimed is:

1. A furnace tube, comprising an outer furnace tube, an inner furnace tube, and a lower furnace door, wherein an upper end and a lower end of an accommodating space between the inner furnace tube and the outer furnace tube are sealed to form a sealed chamber; heating sources used for heating the sealed chamber are arranged on the inner furnace tube and the outer furnace tube; the furnace tube further comprises a rotating device which is provided with a plurality of carrier placement positions corresponding to the sealed chamber; and the rotating device in rotating is capable of driving carriers on the carrier placement positions to adjust positions and angles within the sealed chamber.

2. The furnace tube according to claim 1, wherein an upper end and a lower end of the inner furnace tube are opened, a connecting member used for hoisting connection is arranged at the opening in the upper end, while a support platform is arranged at the opening in the lower end.

3. The furnace tube according to claim 1, wherein a central hole is formed in the middle of the lower furnace door, and a magnetic fluid assembly located at the central hole is arranged outside the lower furnace door; the magnetic fluid assembly is in sealed connection with an inner edge of the lower furnace door and a support base at the bottom of the inner furnace tube; and a transmission shaft connected to the rotating device is arranged at a position, in sealed connection with the lower furnace door and the support base at the bottom of the inner furnace tube, of the magnetic fluid assembly.

4. The furnace tube according to claim 3, wherein the rotating device comprises: a boat holder base which is arranged in the sealed chamber of the furnace tube and provided with the plurality of carrier placement positions, the boat holder base being connected to the transmission shaft on the magnetic fluid assembly; and a rotating power source which is located outside the sealed chamber and connected to the transmission shaft to drive the boat holder base to rotate.

5. The furnace tube according to claim 1, wherein the plurality of carrier placement positions on the rotating device are arranged around the inner furnace tube and are distributed into a plurality of layers in a height direction.

6. The furnace tube according to claim 4, wherein the boat holder base comprises:
a rotating base which is located at the bottom of the sealed chamber; and
a hanging plate which is arranged on the rotating base and is provided with the plurality of carrier placement positions for hanging the carriers.

7. The furnace tube according to claim 6, wherein a heat shield is arranged on the rotating base; the bottom of the hanging plate passes through the heat shield and vertically extends upwards; and a water cooling assembly is mounted in the heat shield.

8. The furnace tube according to claim 4, wherein the boat holder base comprises:
the rotating base which is provided with the plurality of carrier placement positions for allowing carrier boats to pass through or be placed; and
a plurality of pairs of bearing members, each pair of bearing member being located on edges of both sides of one carrier placement position and being arranged on the rotating base in a foldable manner;
after switching the bearing members into a folded state, the carriers are capable of upwards passing through the carrier placement positions corresponding to the bearing members from the bottom; and after switching the bearing members into an unfolded state, the carriers are placed on the bearing members.

9. The furnace tube according to claim 2, wherein an upper furnace cover is mounted at an upper end of the furnace tube; the central hole is formed in the middle of the upper furnace cover; and the central hole in the upper furnace cover is capable of penetrating the upper end of the inner furnace tube or penetrating a hoisting member that is connected to the upper end of the inner furnace tube.

10. The furnace tube according to claim 9, wherein an outer end surface of the upper furnace cover away from the accommodating space protrudes outwards to form a spherical protrusion; a cavity is formed in the upper furnace cover around the periphery of the central hole; and a plurality of reinforcing ribs connected between an upper inner wall and a lower inner wall of the cavity are arranged in the cavity.

11. The furnace tube according to claim 1, wherein a plurality of furnace ports penetrating the lower furnace door are formed in the lower furnace door, and the furnace ports are matched with side surfaces of the carriers in size and shape; each furnace port is correspondingly provided with a furnace cover, and the furnace cover is connected to a driving structure that is used for driving the furnace cover to be opened or closed relative to the furnace port.

12. The furnace tube according to claim 11, wherein the furnace covers and/or the lower furnace door are/is of a spherical protrusion structure that protrudes downwards.

13. The furnace tube according to claim 1, wherein an inner heating source is arranged on an inner side of the inner furnace tube, while an outer heating source is arranged on an outer side of the outer furnace tube; the inner heating source is divided into a plurality of sets of independent heating sections, and heat dissipation devices are correspondingly arranged on the peripheries of the outer heating source and the inner heating source.

14. The furnace tube according to claim 13, wherein the heat dissipation devices are water-cooling type heat dissipation devices or air-cooling type heat dissipation devices; and water-cooling connectors which are in communication with the water-cooling type heat dissipation devices are arranged on the outer furnace tube, the upper furnace cover, and the lower furnace door.

15. A control method for a furnace tube, the furnace tube comprising an outer furnace tube, an inner furnace tube, and a lower furnace door, wherein an upper end and a lower end of an accommodating space between the inner furnace tube and the outer furnace tube are sealed to form a sealed chamber; heating sources used for heating the sealed chamber are arranged on the inner furnace tube and the outer furnace tube; the furnace tube further comprises a rotating device which is provided with a plurality of carrier placement positions corresponding to the sealed chamber; and the rotating device in rotating is capable of driving carriers on the carrier placement positions to adjust positions and angles within the sealed chamber; the control method for the furnace tube comprises the following steps:
opening the lower furnace door;
conveying the carriers to the carrier placement positions on the rotating device;
closing the lower furnace door and performing vacuumizing, and adjusting a reaction environment in the sealed chamber; and
controlling the rotating device to drive the carriers on the carrier placement positions to adjust the positions and angles within the sealed chamber.

16. The control method for the furnace tube according to claim 15, wherein the adjusting the reaction environment in the sealed chamber specifically comprises: starting the heating sources to heat the sealed chamber to reach a preset temperature, and after the sealed chamber reaches the preset temperature, introducing reaction gas into the sealed chamber.

17. The control method for the furnace tube according to claim 15, wherein the controlling the rotating device to drive the carriers on the carrier placement positions to adjust the positions and angles within the sealed chamber specifically comprises:
driving the carriers on the carrier placement positions to rotate around the inner furnace tube, and adjusting the rotating direction and rotating duration in each rotating direction according to a preset rotating logic.
